(19) United States
(12) Patent Application Publication
(10) Pub. No.: US 2004/0261707 A1
(43) Pub. Date: Dec. 30, 2004

(54) Apparatus for and method of cooling and positioning a translating substrate tape for use with a continuous vapor deposition process

(76) Inventors: Venkat Selvamanickam, Wynantskill, NY (US); Srinivas Sathiraju, Riverside, OH (US)

Correspondence Address: KATTEN MUCHIN ZAVIS ROSENMAN, 575 MADISON AVENUE, NEW YORK, NY, 10022-2585, US

(21) Appl. No.: 10/609,236

(22) Filed: Jun. 26, 2003

(51) Int. Cl. C23C 16/00

(52) U.S. Cl. 118/718; 118/728

(57) ABSTRACT

The present invention is an apparatus for and method of cooling and positioning a translating substrate tape during a continuous high-throughput deposition process such as IBAD that is characterized by a long deposition zone where the substrate tape comes into contact with a substrate assembly as it translates the length of the deposition zone. A chilled liquid passes through the substrate assembly, maintaining the temperature of the substrate assembly below a specified level. Also passing through the substrate assembly is an inert gas that exits at an interface between the translating tape and the substrate assembly.

### FIELD OF THE INVENTION

The present invention relates to high-throughput IBAD systems. More specifically, the present invention relates to a substrate cooling and support structure that positions and removes heat from a translating metal substrate tape as the tape translates through a deposition zone of such a length that characterizes high-throughput IBAD systems.

### BACKGROUND OF THE INVENTION

Wire forms the basic building block of the world's electric power system, including transformers, transmission and distribution systems, and motors. The discovery of revolutionary high-temperature superconducting (HTS) compounds in 1986 led to the development of a radically new type of wire for the power industry; this discovery is the most fundamental advance in wire technology in more than a century. However, to date only short samples of the HTS tape used in the manufacture of next-generation HTS wires have been fabricated at high performance levels. In order for HTS technology to become commercially viable for use in the power generation and distribution industry, it will be necessary to develop techniques for continuous, high-throughput production of HTS tapes.

Ion beam-assisted deposition (IBAD) has become a convincing candidate for enabling the cost-effective high-throughput thin film growth necessary to realize widespread adaptation of superconducting materials in the electricity transmission/distribution industry. IBAD is described in U.S. Pat. No. 6,258,472, entitled “Product having a substrate of a partially stabilized zirconium oxide and a buffer layer of a fully stabilized zirconium oxide, and process for its production.” IBAD has been shown to be particularly well suited for depositing the buffer layers such as of yttrium-stabilized zirconia (YSZ) and cerium oxide (CeO₂) that serve as a support for a functional layer of a ceramic superconducting material, such as yttrium-barium-copper-oxide (YBCO), atop the buffering layers

During IBAD, a vacuum-deposition process occurs that combines physical vapor deposition (PVD) with ion beam bombardment. A vapor of coating atoms is generated with an electron beam evaporator and deposited on a substrate such as a translating metal tape. Ions are simultaneously extracted from a source and accelerated into the growing PVD film at energies of a few hundred electron-volts (eV). The ions impart substantial energy to the coating and coating/substrate interface, driving the depositing species into the substrate and enhancing adhesion by producing a graded material interface. These factors combine to enable the deposition of uniform, adherent, low-stress buffer layer films ideal for subsequent superconducting thin film deposition. In addition, concurrent ion beam bombardment of a growing film has been shown to impart biaxial texture. IBAD has been specifically used for this purpose to achieve a high-degree of biaxial texture in materials used as buffer layers for HTS tapes.

While prior art IBAD processes, such as described in Neumuller, et al., U.S. Pat. No. 6,258,472, dated Jul. 10, 2001 and entitled Product Having A Substrate Of A Partially Stabilized Zirconium Oxide And A Buffer Layer Of A Fully Stabilized Zirconium Oxide, And Process For Its Production are well known for their uniform and adherent thin film qualities, they are limited in the throughput they can achieve, and thus fail to produce HTS material in the cost-effective manner necessary to enable the widespread adaptation of such materials in the electricity transmission/distribution industry. Key to enabling a high-throughput system is the achievement of a large deposition zone. The size of the deposition zone determines the area onto which thin film deposition atop a substrate may occur. Consequently, an IBAD system characterized by a long deposition zone may enable metal substrate tapes to translate through the system and receive an optimum thin film deposition at velocities sufficient to achieve desirable throughput levels. However, innovations must be made to accommodate increased deposition zone lengths before a high-throughput IBAD system can be realized, including ways to optimally position, monitor, and maintain the temperature of the tape as it traverses the entire length of the deposition zone.

Such a translating substrate tape must be maintained at a precise angle relative to the impinging ion beam throughout the entirety of the deposition zone to ensure proper film properties. Any flex experienced by the tape causes the angle between the tape and the ion beam to change and regions of compromised thin film uniformity to develop.

The long deposition zone that characterizes a high-throughput IBAD system presents significant tape-cooling issues not present in systems with smaller deposition zones, such as described in Neumuller, et al. The deposition process induces heat in the tape that must be removed to stabilize the deposited films. This heating can raise the tape temperature to levels at which the product becomes unusable due to degrading effects on the deposited film. Existing cooling techniques utilize simple conduction to remove excess heat from substrates and are ineffective for high-throughput IBAD systems because the translational motion of the tape reduces the thermal contact between the tape and the cooling structure, causing erratic cooling.

Further, it is desirable to monitor the temperature of the tape and the substrate support temperature at different points throughout such a long deposition zone in order to obtain feedback about how deposition is proceeding and in order to enable process parameters to be adjusted to optimize the process. However, it is desirable to make such measurements without making physical contact with the translating tape, as any motion between the tape and a conductive temperature-sensing device reduces thermal contact and results in inaccurate temperature readings.

It is therefore an object of the invention to provide a substrate assembly for use in high-throughput IBAD systems that is capable of optimally positioning a translating substrate tape throughout the entirety of the long deposition zone associated with such a system.

It is yet another object of the invention to provide a substrate assembly for use in high-throughput IBAD systems that is capable of maintaining a translating substrate tape at an optimum deposition temperature throughout the entirety of the long deposition zone associated with such a system.

It is yet another object of the invention to provide a substrate assembly for use in high-throughput IBAD systems that allows in situ tape temperature measurement without a temperature-sensing device making physical contact with the tape.

### BRIEF SUMMARY OF THE PRESENT INVENTION

The present invention is an apparatus for and method of cooling and positioning a translating substrate tape. The substrate tape comes into contact with the apparatus, hereafter referred to as a substrate assembly, as it translates the length of the deposition zone of a high-throughput IBAD or other coating system. A chilled liquid passes through internal passages of the substrate assembly, maintaining the temperature of the substrate assembly below a specified level. Also passing through internal channels in the substrate assembly is an inert gas that exits at an interface between the translating tape and the substrate assembly. The thermal contact between the substrate assembly and the tape results in conductive cooling of the tape, while the flow of gas against the tape induces convective cooling. The substrate assembly is of sufficient length to maintain the tape at a desired position with respect to the impinging ion beam throughout the entire length of the deposition zone to ensure optimum film properties.

The substrate assembly further includes a sapphire waveguide in communication with a pyrometer. The waveguide provides an optical pathway for infrared (IR) temperature measurements of the non-exposed side of the translating substrate tape without making physical contact with the tape.

### BRIEF DESCRIPTION OF THE DRAWINGS

FIG. 1 illustrates a high-level block diagram of an IBAD system.

FIG. 2 illustrates a front view of an IBAD chamber assembly apparatus.

FIG. 3A is a first cross-sectional view of the substrate assembly taken along line A-A of FIG. 2.

FIG. 3B is a second cross-sectional view of the substrate assembly taken along line B-B of FIG. 3A.

FIG. 4A illustrates a side view of a first embodiment of the substrate block portion of the substrate assembly of the present invention.

FIG. 4B illustrates a side view of a second embodiment of the substrate block portion of the substrate assembly of the present invention.

FIG. 5 illustrates a method for cooling a substrate assembly and a translating metal tape.

### DETAILED DESCRIPTION OF THIS INVENTION

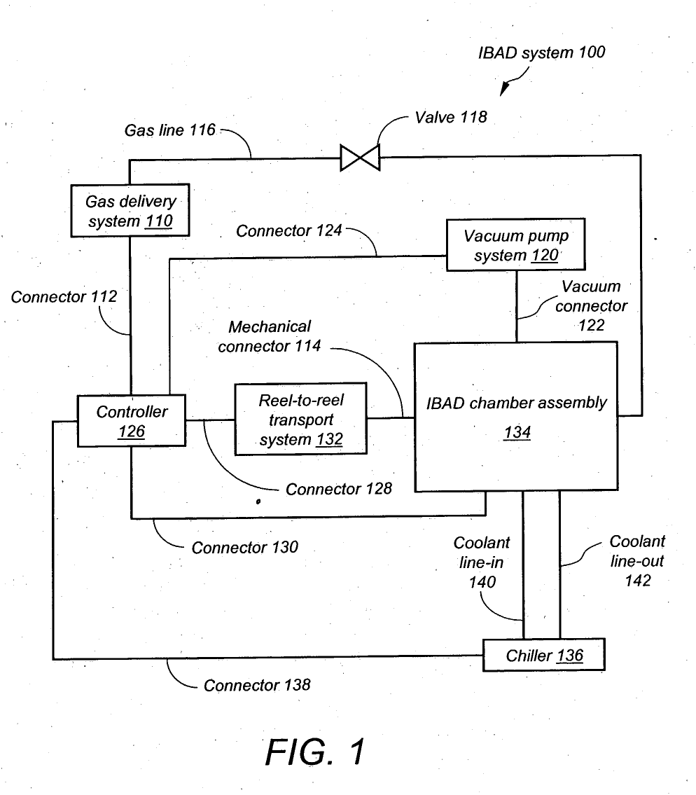

FIG. 1 illustrates a high-level block diagram of an IBAD system 100 in accordance with the invention, depicting the functional relationships between each subsystem. The IBAD system 100 includes a plurality of subsystems as follows:

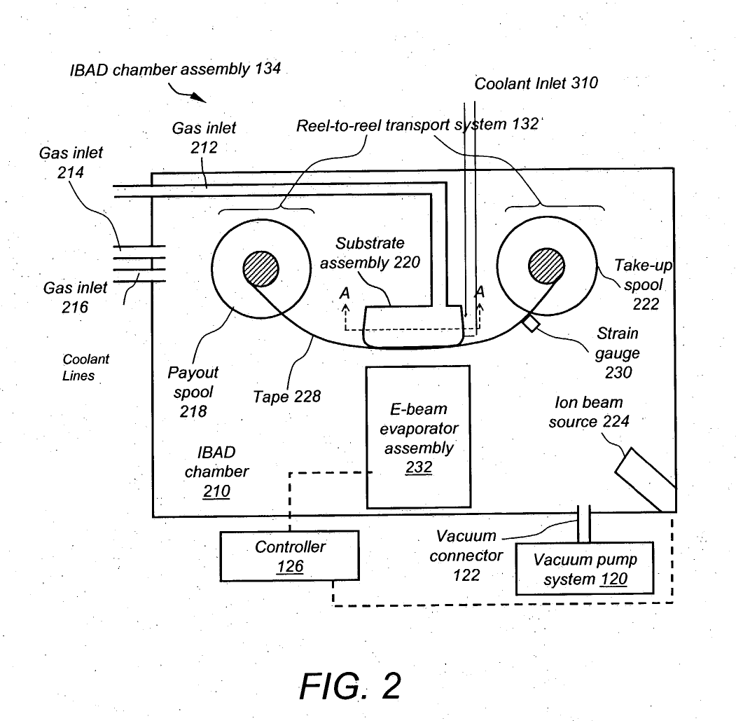

An IBAD chamber assembly 134 that includes an IBAD chamber and other elements. The IBAD chamber assembly 134 is described in detail in reference to FIG. 2.

A gas delivery system 110 that provides gas through a gas line 116 and a valve 118 to the IBAD chamber assembly 134 at a desired flow rate to meet process specifications. The gas line 116 may include one or more separate pathways for different gases.

A vacuum pump system 120 that is a commercially available vacuum pump and associated equipment capable of drawing air or other gases from the IBAD chamber assembly 134 through a vacuum connector 122, and maintaining a vacuum pressure of the order of magnitude of 10⁻⁵, preferably 10⁻⁷ Torr. One example of such a pump is an APD Cryogenics, Marathon 16 cryopump.

A chiller 136 that is a standard refrigeration device through which liquid refrigerants flow. Such liquids may include deionized water, deionized water with glycol, and liquid nitrogen. A refrigeration loop is created between the chiller 136 and the IBAD chamber assembly 134 via a coolant line-in 140 and a coolant line-out 142.

A reel-to-reel transport system 132 that is a spooling system that serves to translate a length of metal substrate tape in a linear fashion through the IBAD chamber assembly 134 while maintaining optimum tape tension, position, and speed. The reel-to-reel transport system 132 is connected through the IBAD chamber assembly 134 via a mechanical connector 114.

Lastly, the IBAD system 100 includes a controller 126 with a plurality of inputs and outputs that meet the requirements of the peripherals described in reference to FIGS. 1 and 2. The controller 126 may be one or more micro-controllers or a PC with appropriate hardware and software. The controller 126 is electrically coupled to and provides control to the gas delivery system 110 via a connector 112, to the vacuum pump system 120 via a connector 124, to the chiller 136 via a connector 138, to the reel-to-reel transport system 132 via a connector 128, and to elements of the IBAD chamber assembly 134 described in reference to FIG. 2 via a connector 130.

In operation and in continuing reference to FIG. 1, the controller 126 operates the vacuum pump system 120 through the connector 124, evacuating the IBAD chamber assembly 134 through the vacuum connector 122. The controller 126 then operates the gas delivery system 110 through the connector 112, delivering controlled levels of ambient gas through the gas line 116 and the valve 118 to the IBAD chamber assembly 134. Through the connector 128, the controller 126 operates the reel-to-reel transport system 132, which, in turn, controls the tape transport through the IBAD chamber assembly 134 through the mechanical connector 114. The controller 126 communicates through the connector 130 to operate elements within the IBAD chamber assembly 134, as described in reference to FIG. 2.

The controller 126 communicates through the connector 138 to operate the chiller 136. The chiller 136 cools down a liquid refrigerant, and the refrigerant flows into the IBAD chamber assembly 134 through the coolant line-in 140. Warmer liquid returns from the IBAD chamber assembly 134 through the coolant line-out 142 to be recycled through the chiller 136.

FIG. 2 illustrates a front view of the IBAD chamber assembly 134. As this view shows, the IBAD chamber assembly 134 further includes an IBAD chamber 210 that is a pressurized vacuum chamber. The IBAD chamber 210 may be constructed of any non-corroding metal, such as 304 stainless steel. The IBAD chamber 210 includes all the necessary gaskets, seals, and seal plates to maintain a vacuum to the order of 10⁻⁵ preferably 10⁻⁷ Torr.

As shown in FIG. 2, the vacuum pump system 120 connects via the vacuum connector 122 disposed in the outer wall of the IBAD chamber 210. This arrangement evacuates the IBAD chamber 210 to approximately 10⁻⁷ Torr.

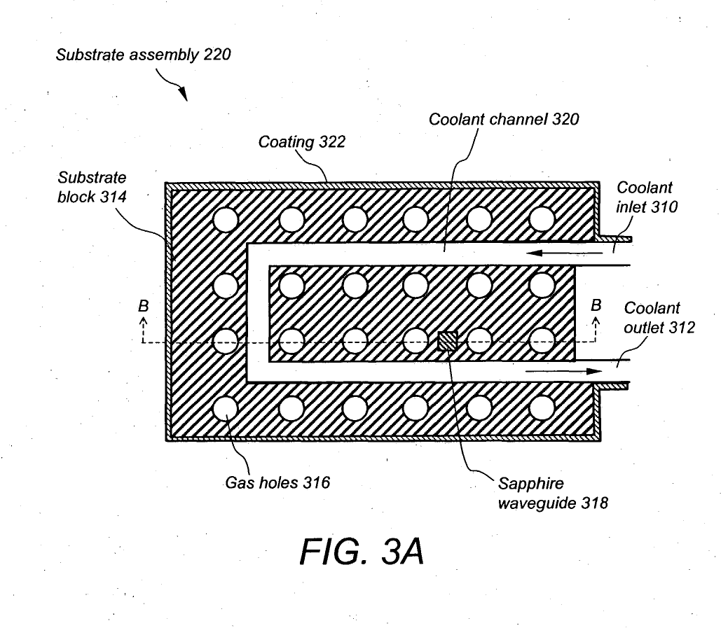

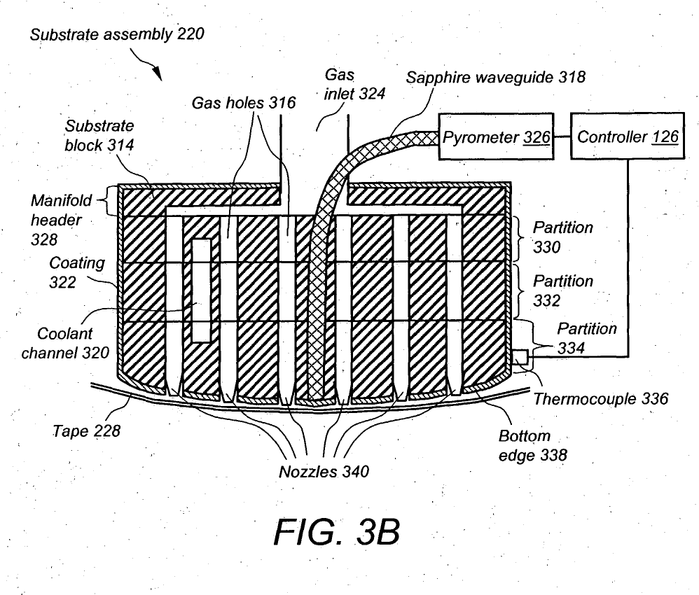

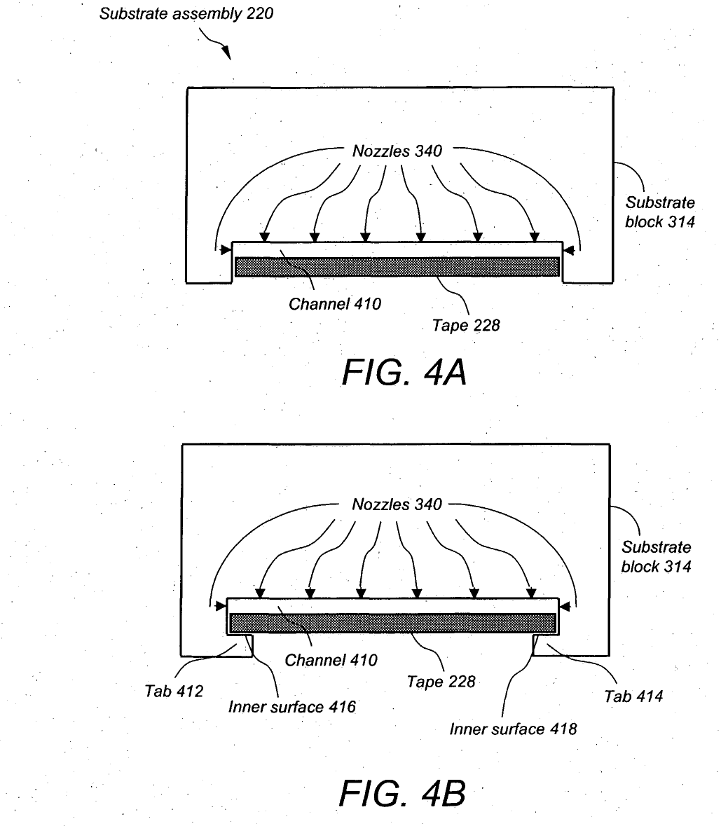

A substrate assembly 220, which is described in detail in reference to FIGS. 3 and 4, is suspended in the IBAD chamber 210 such that a deposition zone is created at the surface of the substrate assembly 220. A tape 228 comes into contact with and translates in a linear fashion underneath the substrate assembly 220 via the action of a payout spool 218 and a take-up spool 222 of the reel-to-reel tape transport system 132, which may or may not be disposed inside the IBAD chamber 210. The payout spool 218 is a spool from which the tape 228 unwinds as the tape 228 translates through the IBAD chamber 210. The take-up spool 222 is the spool onto which the tape 228 winds subsequent to undergoing the IBAD process. The diameter and width of the payout spool 218 and the take-up spool 222 may vary with the dimensions of the desired product and are constructed from a variety of materials capable of withstanding vacuum chamber conditions. Other elements (not shown) of the reel-to-reel tape transport system 132 control the tape speed, tension, and position as the tape 228 translates through the IBAD chamber 210. Additionally, a strain gauge 230 is disposed so as to make contact with the tape 228. The strain gauge 230 is a sensing device capable of measuring the tension in the tape 228 and is well known to the art.

The tape 228 is an extended length of substrate formed from a variety of metals, such as stainless steel or a nickel alloy such as Inconel. The tape 228 is capable of withstanding temperatures up to 900° C. The dimensions of the tape 228 may vary to meet the desired finished product and system limitations. For example, the tape 228 may have a thickness of 25 microns, a width of 1 cm, and a length of 100 meters.

A gas inlet 212, a gas inlet 214, and a gas inlet 216 are disposed through the outer wall of the IBAD chamber 210 and are fed by the gas delivery system 110 via the gas line 116. The gas inlets 214 and 216 open into the IBAD chamber 210, while the gas inlet 212 connects directly to the substrate assembly 220. Consequently, three separate, sealed gas flow lines are formed between the gas delivery system 110 and the IBAD chamber 210.

Also disposed within the IBAD chamber 210 is an electron-beam (e-beam) evaporator assembly 232 horizontally aligned with the center of the substrate assembly 220. The e-beam evaporator assembly 232 is an apparatus that vaporizes material from a cylinder of solid material by means of electron beam heating, as is well known to the art.

Other energy sources, such as magnetron or ion-beam sputtering sources, (not shown) may be used to vaporize the coating material instead of the electron-beam source.

Further, an ion beam source 224 is disposed within the IBAD chamber 210 in such a manner that a beam of ions (not shown) emitted therefrom is directed toward the tape 228 at an incident angle of, for example, 55 degrees. The ion beam source 224 is a commercially available ion gun that directs a stream of positive ions at the tape 228 to bombard the material embedded on the tape 228 as it accumulates by vapor deposition.

In operation and in continuing reference to FIG. 2, the IBAD chamber 210 is evacuated by the vacuum pump 120. The gas inlets 212, 214, and 216 funnel gas into the IBAD chamber 210. The reel-to-reel transport system 132 mechanically rotates the payout spool 218 and the take-up spool 222, thereby translating the tape 228 over the substrate assembly 220 at speeds between 0.5 to 100 meters per hour. The tape 228 is within the deposition zone of the IBAD system 100 as it translates across the substrate assembly 220. Within the deposition zone, a buffer layer such as cerium oxide (CeO₂) or yttria-stabilized zirconium (YSZ) is deposited atop the tape 228 as material evaporated from the e-beam evaporator assembly 232 and ions emitted from the ion beam source 224 impinge upon the tape 228. The tape 228 contacts the strain gauge 230 prior to winding onto the take-up spool 222, and a tension measurement is made.

FIG. 3A is a first cross-sectional view of the substrate assembly 220 taken along line A-A of FIG. 2. This view shows that the substrate assembly 220 further includes a substrate block 314 having a coating 322 such as YSZ covering outer surface of the substrate block 314. Within the substrate block 314 is disposed a coolant channel 320 having a coolant inlet 310 and a coolant outlet 312. The coolant channel 320 is a metal pipe that runs through a channel in the partition blocks. The coolant channel 320 may be the single U-shaped pipe illustrated. The coolant channel 320 may also be shaped in multiple other ways, such as a curved pipe that runs in alternating directions, to increase the inner surface area of the substrate block 314 that contacts the coolant channel 320.

The substrate assembly 220 further includes a plurality of gas holes 316 and a sapphire waveguide 318, which is a sapphire optical fiber that is transparent to infrared wavelengths.

FIG. 3B is a second cross-sectional view of the substrate assembly 220 taken along line B-B of FIG. 3A. The cross-sectional view of FIG. 3B is perpendicular to the cross-sectional view of FIG. 3A. This view shows that the substrate assembly 220 includes the substrate block 314, through which is disposed a gas inlet 324 (fed by the gas inlet 212) that branches into multiple rows of multiple gas holes 316, each of which are approximately 0.025 to 0.4 mm in diameter and terminates in one of a plurality of orifices or nozzles 340 disposed through a bottom edge 338 of the substrate block 314. The substrate block 314 is further shown to include a manifold header 328, a partition 330, a partition 332, and a partition 334. alternatively, partitions 332 and 334 may be replaced by a unitary block. The manifold header 328 is a metallic, preferably copper,m block placed on top of the partition 330; a cavity machined in the manifold header 328 covers all the gas holes 316. Each gas hole 316 is drilled completely through the partitions 330, 332, and 334. The partitions 330, 332, and 334 are metallic, preferably copper, blocks stacked on top of one another to form the structure of the substrate block 314. A pyrometer 326 is shown optically connected to the sapphire waveguide 318. The controller 126 is in communication with the pyrometer 326 and one or more thermocouples 336. The pyrometer 326 is a standard optical pyrometer for measuring temperature. The thermocouples 336 are standard transducers used for temperature measurement.

The bottom edge 338 on the partition 334 is rounded in the plane shown in FIG. 3B to a radius of curvature of about 20 feet to allow the tape 228 to be positioned against the bottom edge 338.

In operation, an inert gas from the gas delivery system 116, such as nitrogen, argon, or helium, enters through the gas inlet 212 that subsequently feeds the gas inlet 324 and proceeds to the manifold header 328. The manifold header 328 distributes the gas evenly into all the gas holes 316 and the gas proceeds out the orifices or nozzles 340. The gas forms a cushion over which the tape 228 translates. This gas flow pattern reduces contact between the tape 228 and the bottom edge 338, thus enhancing heat removal from the tape 228. The expansion of gas as it issues forth through the orifices of nozzles 340 further cools the gas and enhances heat removal from the tape 228. The gas flow is kept to a flow pressure of less than one standard cubic centimeter per minute (SCCM). The radius of curvature of the bottom edge 338 is sufficiently large that the tape 228 maintains the correct angle with respect to the ion beam source 224.

In an alternative embodiment of the invention the inert gas is replaced in whole or in part by oxygen.

In yet another embodiment of the invention, two separate gas systems are utilized; one supplying inert gas, the other oxygen.

Simultaneously, liquid coolant from the chiller 136 flows through the coolant line-in 140, into the coolant inlet 310, through the coolant channel 320, out the coolant outlet 312, through the coolant line-out 142, and back to the chiller 136 to be recycled through the coolant system. The cooling effect of the liquid from the chiller 136 and the gas flow through the substrate assembly 220 and out the orifices or nozzles 340 maintains the temperature of the substrate block 314 within specifications, e.g., below 50° C.

Infrared radiation from heat at the bottom edge 338 travels upward through the sapphire waveguide 318 and enters the pyrometer 326. The pyrometer 326 measures the radiation carried by the sapphire waveguide 318 and transmits that information in the form of a temperature at the bottom edge 338 to the controller 126. In the same way, the thermocouples 336 transmit temperatures to the controller 126 from various locations on the substrate assembly 220, ensuring that no part of the substrate block 314 is overheating. The controller 126 can then adjust the controls in the chiller 136 to raise or lower the temperature of the liquid coolant, alter the flow rate of the liquid coolant, or alter the flow of the gas to keep the temperature of the substrate block 314 within specifications.

FIG. 4A illustrates a side view of a first embodiment of the substrate block 314 of the substrate assembly 220 of the present invention. In the side view of the substrate block 314 illustrated in FIG. 4A, the substrate assembly 220 includes all the components shown in FIGS. 3A and 3B; however, some have been omitted from FIG. 4 for clarity. FIG. 4A includes the substrate block 314, the orifices or nozzles 340, the tape 228, and a channel 410. FIG. 4B includes the substrate block 314, the orifices or nozzles 340, the tape 228, the channel 410, a tab 412, a tab 414, an inner surface 416, and an inner surface 418.

In the substrate block 314 of FIG. 4A, the channel 410 is cut to a width slightly larger than the width of the tape 228. One or more additional orifices or nozzles 340 can be cut into the sides of the channel 410, as shown in FIG. 4A. The tape 228 is accommodated in the channel 410, which keeps the tape 228 centered on the substrate block 314. In addition, when the tape 228 is accommodated in the recessed channel 410, less gas exiting the orifices or nozzles 340 leaks into the IBAD chamber 210, while maintaining sufficient pressure to keep the tape 228 separated from the bottom edge 338. Therefore, there is less ambient gas interfering with ions issued from the ion beam source 224 and directed at the tape 228.

FIG. 4B illustrates a side view of a second embodiment of the substrate block 314 of the substrate assembly 220 of the present invention. FIG. 4B illustrates a variation of the substrate block 314 in which tabs 412 and 414 are attached to or machined from the substrate block 314. The inner surfaces 416 and 418 of the tabs 412 and 414, respectively, are coated with Teflon™ or a similar substance to decrease friction with the tape 228, which is pushed against the Teflon™ surface by the pressure of the gas exiting the orifices or nozzles 340. This embodiment provides an even better gas seal for the purposes stated above. The tabs 412 and 414 are small enough so as not to obstruct the ions from impinging on the tape 228.

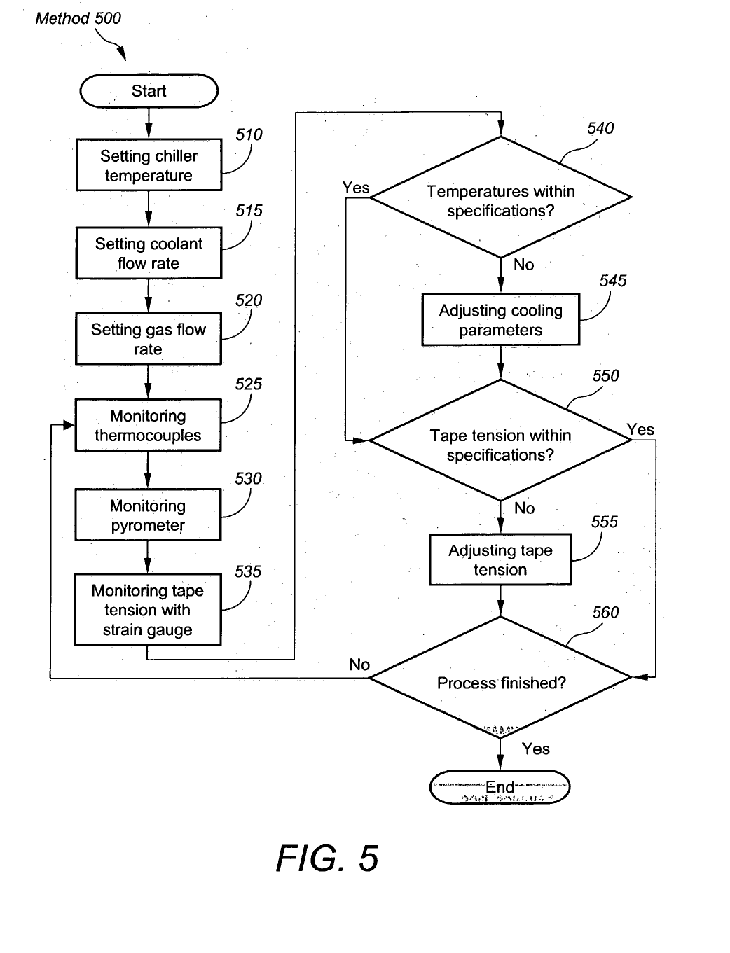

FIG. 5 shows a method 500 for cooling the substrate assembly 220 and the translating tape 228 using a liquid coolant flow and gas convective thermal transfer, in accordance with the invention. The method 500 starts at the same time and runs concurrently with the process that runs the entire IBAD system 100. The method 500 includes the following steps:

Step 510: Setting Chiller Temperature

In this step, an operator or the controller 126 sets the initial temperature of the liquid coolant that maintains the temperature of the substrate block 314 within specifications.

Step 515: Setting Coolant Flow Rate

In this step, the operator or the controller 126 sets the flow rate of the liquid coolant that maintains the temperature of the substrate block 314 within specifications.

Step 520: Setting Gas Flow Rate

In this step, the operator or the controller 126 sets the gas flow rate through the substrate block 314, the gas holes 316, and the orifices or nozzles 340. The rate is high enough to maintain a cushion of gas between the tape 228 that is translating in a linear fashion and the bottom edge 338, and is lower than one SCCM.

Step 525: Monitoring Thermocouples

In this step, the operator, in conjunction with the controller 126, monitors the surface temperature of the substrate block 314 to ensure that the temperature throughout the substrate block 314 is within specifications.

Step 530: Monitoring Pyrometer

In this step, the operator, in conjunction with the controller 126, monitors the temperature of the bottom edge 338 with data from the pyrometer 326 to ensure that the temperature is within specifications.

Step 535: Monitoring Tape Tension with Strain Gauge

In this step, the operator, in conjunction with the controller 126, monitors the tension on the translating tape 228 from data gathered by the strain gauge 230. If the tension is too high, the tape 228 could stretch or break; if the tension is too low, the tape 228 can sag too far from the substrate block 314.

Step 540: Temperatures within Specifications?

In this decision step, the operator or the controller 126 determines whether all temperatures measured by the pyrometer 326 and/or the thermocouples 336 are within specifications, typically less than 50° C. If so, the method 500 proceeds to step 550; if not, the method 500 proceeds to step 545.

Step 545: Adjusting Cooling Parameters

In this step, the operator or the controller 126 adjusts the thermostat on the chiller 136, the liquid coolant flow rate, the gas flow rate, or any combination of these three to bring the temperature of the substrate block 314 back to within specifications.

Step 550: Tape Tension within Specifications?

In this decision step, the operator or the controller 126 determines whether the tension of the translating tape 228 is within specifications. If so, the method 500 proceeds to step 560; if not, the method 500 proceeds to step 555.

Step 555: Adjusting Tape Tension

In this step, the operator or the controller 126 adjusts the tension of the translating tape 228 to within specifications using various means, such as adjusting the torque of the take-up spool 222.

Step 560: Process Finished?

In this decision step, the operator or the controller 126 determines whether the method 500 is finished, based on criteria that may include the length of tape 228 collected by the take-up spool 222, the length of time that the IBAD system 100 has continually run, or other process engineering parameters. If it is decided that the method 500 is finished, the method 500 ends; otherwise, the method 500 returns to step 525.

1. An apparatus for cooling and positioning a translating substrate during a continuous high-throughput coating deposition process comprising
a deposition chamber comprising a vacuum chamber, a gas inlet, a source of deposition material for coating the substrate, a means for delivering the deposition material from the deposition source to the surface of the substrate;
a substrate;
a means of translating a substrate to be coated through the deposition chamber;
and
a means for positioning the substrate in a deposition zone where deposition material impinges upon the surface of the substrate,
wherein the substrate positioning means contains internal liquid coolant channels and internal gaseous coolant delivery channels.

2. The apparatus of claim 1 where the internal gaseous coolant delivery channels are connected by a manifold to the gas inlet and where the channels open to the deposition chamber through orifices at multiple points where the substrate assembly contacts the translating substrate.

3. The apparatus of claim 1 where the means for delivering the deposition material is an electron beam energy source.

4. The apparatus of claim 1 where the means for delivering the deposition material is an ion beam energy source.

5. The apparatus of claim 1 where the means for delivering the deposition material is a magnetron energy source.

6. The apparatus of claim 1 where the substrate positioning means is coated with the material being deposited.

7. The apparatus of claim 2 where the diameter of the gas orifices are in the range of from about 0.025 to about 0.4 inches.

8. The apparatus of claim 2 where the diameter of the gas orifices are in the range of from about 0.05 to about 0.25 inches.

9. The apparatus of claim 2 where the diameter of the gas orifices are in the range of from about 0.075 to about 0.175 inches.

10. The apparatus of claim 2 where the multiple orifices are located no more than three inches apart.

11. The apparatus of claim 2 where there the multiple orifices are positioned such that there are from one to about twelve orifices every three inches.

12. A method of cooling and positioning at least one translating substrate during a continuous high-throughput coating deposition process comprising
providing a feed spool of substrate,
unspooling and threading the substrate through a vacuum deposition chamber,
loading into the vacuum deposition chamber coating material that is to be deposited onto a surface of the substrates,
reducing the pressure in the deposition chamber to no greater than about 10⁻⁵ Torr,
initializing an energy source located in the deposition chamber to a predetermined power level and trajectory,
vaporizing the surface of the coating material utilizing energy from the energy source,
feeding the substrates through a deposition zone in the vacuum chamber,
maintaining the temperature of the tape in the deposition zone at a preselected temperature by contacting the tape with a cooling and positioning means;
injecting at least one gas selected from the group consisting of inert gases and oxygen onto the substrate and into the deposition chamber through the cooling and positioning means,
allowing the vaporized coating material to impinge upon a surface of the substrates in the deposition zone for a period of time sufficient to deposit a coating of eroded coating material onto the substrates, and
collecting the coated substrates on individual take-up spools.

13. The method of claim 12 where the energy source is an electron beam energy source.

14. The method of claim 12 where the energy source is an ion beam energy, source.

15. The method of claim 12 where the energy source is a magnetron energy source.

16. The method of claim 12 where the cooling and positioning means is a substrate positioning assembly containing internal liquid coolant channels and internal gaseous coolant delivery channels.

17. The method of claim 12 where the temperature at the surface of the substrate when in heat transfer relationship with the substrate positioning means is maintained at a temperature below 50° C.

18. The method of claim 12 where the cooling and positioning means contains internal gas delivery channels connected by a manifold to a gas source and which open to the deposition chamber through nozzles at multiple points where the substrate assembly contacts the translating substrate and gas is flowed through the nozzles as the substrate translates through the deposition zone.

19. The method of claim 16 where the liquid coolant is deionized water with or without glycol or liquid nitrogen.

20. The process of claim 12 where the translation speed is in the range of from about 0.4 to about 300 meters/hour.

21. The process of claim 12 where the translation speed is in the range of from about 0.5 to about 5 meters/hour and the material being deposited is YSZ.

22. The process of claim 12 where the translation speed is in the range of from about 20 to about 300 meters/hour and the material being deposited is MgO.

23. The method of claim 12 where the gas is selected from the group consisting of N₂, Ar, He or O₂.

24. The method of claim 12 where the gas is O₂.
